(19) United States
(12) Patent Application Publication
(10) Pub. No.: US 2025/0014943 A1
(43) Pub. Date: Jan. 9, 2025

(54) Surface Profile Control Of Passivation Layers In Integrated Circuit Chips

(71) Applicant: Taiwan Semiconductor Manufacturing Co., Ltd., Hsinchu (TW)

(72) Inventors: Zheng Yong LIANG, Kaohsiung City (TW); Wei-Ting YEH, Hsinchu City (TW); I-Han HUANG, New Taipei City (TW); Chen-Hao WU, Hsinchu (TW); An-Hsuan LEE, Hsinchu (TW); Huang-Lin CHAO, Hsinchu (TW); Yu-Yun PENG, Hsinchu (TW); Keng-Chu LIN, Hsinchu (TW)

(73) Assignee: Taiwan Semiconductor Manufacturing Co., Ltd., Hsinchu (TW)

(21) Appl. No.: 18/219,259

(22) Filed: Jul. 7, 2023

(51) Int. Cl. H01L 21/768; H01L 21/3105; H01L 23/00; H01L 29/66

(52) U.S. Cl. CPC H01L 21/76819; H01L 21/31053; H01L 24/08; H01L 24/80; H01L 29/66795; H01L 2224/08145; H01L 2224/80896

(57) ABSTRACT

An integrated circuit (IC) chip with polish stop layers and a method of fabricating the IC chip are disclosed. The method includes forming a first IC chip having a device region and a peripheral region. Forming the first IC chip includes forming a device layer on a substrate, forming an interconnect structure on the device layer, depositing a first dielectric layer on a first portion of the interconnect structure in the peripheral region, depositing a second dielectric layer on the first dielectric layer and on a second portion of the interconnect structure in the device region, and performing a polishing process on the second dielectric layer to substantially coplanarize a top surface of the second dielectric layer with a top surface of the first dielectric layer. The method further includes performing a bonding process on the second dielectric layer to bond a second IC chip to the first IC chip.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), fin field effect transistors (finFETs), and gate-all-around (GAA) FETs in integrated circuit (IC) chips. To further reduce the two-dimensional footprint of the semiconductor devices, the IC chips are stacked together to form three-dimensional ICs (3DICs). The scaling down has increased the complexity of manufacturing 3DICs.

### BRIEF DESCRIPTION OF THE DRAWINGS

Aspects of this disclosure are best understood from the following detailed description when read with the accompanying figures.

FIG. 1A illustrates an isometric view of a 3DIC, in accordance with some embodiments.

FIGS. 1B-1E illustrate different cross-sectional views of a 3DIC with polish stop layers, in accordance with some embodiments.

FIG. 2 is a flow diagram of a method for fabricating a 3DIC with polish stop layers, in accordance with some embodiments.

FIGS. 3-7 illustrate cross-sectional views of a 3DIC with polish stop layers at various stages of its fabrication process, in accordance with some embodiments.

FIG. 8 is a flow diagram of a method for fabricating another 3DIC with polish stop layers, in accordance with some embodiments.

FIGS. 9-16 illustrate cross-sectional views of another 3DIC with polish stop layers at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

An integrated circuit (“IC”) chip can include a compilation of layers with different functionality, such as interconnects, power distribution network, logic chips, memory chips, radio frequency (RF) chips, and the like. A three-dimensional (3D) integrated circuit (3DIC) is a non-monolithic vertical structure developed based on the IC chip and can include, for example, two to eight two-dimensional (2D) IC chips stacked on top of each other and bonded to each other with bonding layers. The bonding reliability of 3DICs can depend on the surface profiles of the bonding layers and/or on substantially planarized surface area dimensions of the bonding layers. The scaling down of IC chips has increased the challenges of forming substantially planarized bonding layers in reduced surface areas of the bonding layers.

To address the abovementioned challenges, the present disclosure provides example polish stop layers (PSLs) in IC chips and methods of forming the PSLs to form bonding layers with substantially planar surface profiles and/or with minimized surface height variations (e.g. about 1 nm to about 30 nm) from centers to edges of the bonding layers. The PSL can prevent or minimize edge roll-off of the bonding layer at and/or near edges of device regions in the IC chip to eliminate or minimize the surface height variation from the center to the edge of the bonding layer and increase the dimension of substantially planarized surface areas of the bonding layer. Increasing the substantially planarized surface area dimensions can increase the bonding regions of the IC chips and improve the bonding interfaces between the stacked IC chips in 3DICs, thus improving the bonding reliability of the 3DICs.

In some embodiments, with the use of PSL, the bonding layer can be formed with a surface height variation of about 1 nm to about 30 nm from the center to the edges of the bonding layer. In some embodiments, the PSL can be formed in the peripheral regions of the IC chip prior to forming the bonding layer in the device regions of the IC chip. The PSL can include a material with a higher polishing resistance than that of the material of the bonding layer. The highly polish resistant PSL can prevent or minimize the roll-off of the bonding layer at and/or near the edges of the devices regions during a polishing process (e.g., chemical mechanical polishing (CMP) process). The edge roll-off of the bonding layer can be due to a higher concentration of polishing stress at and/or near the edges of the device regions compared to the centers of the device regions. The edge roll-off of the bonding layer can also be due to the formation of the bonding layer on non-planar surfaces of underlying layers in the peripheral regions. The non-planar surfaces of the underlying layers can be due to the formation of the underlying layers on beveled surfaces in the peripheral regions of the substrate of the IC chip.

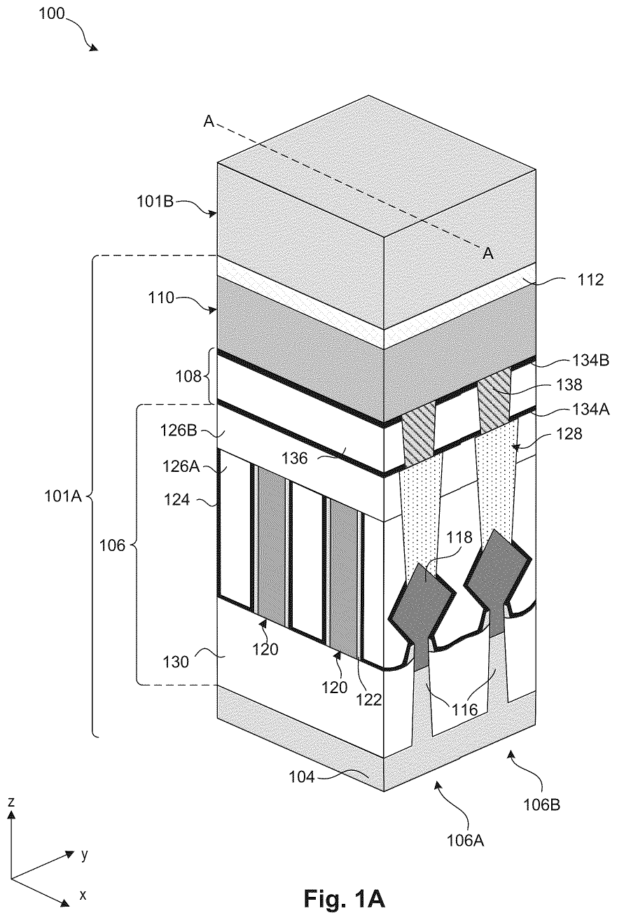

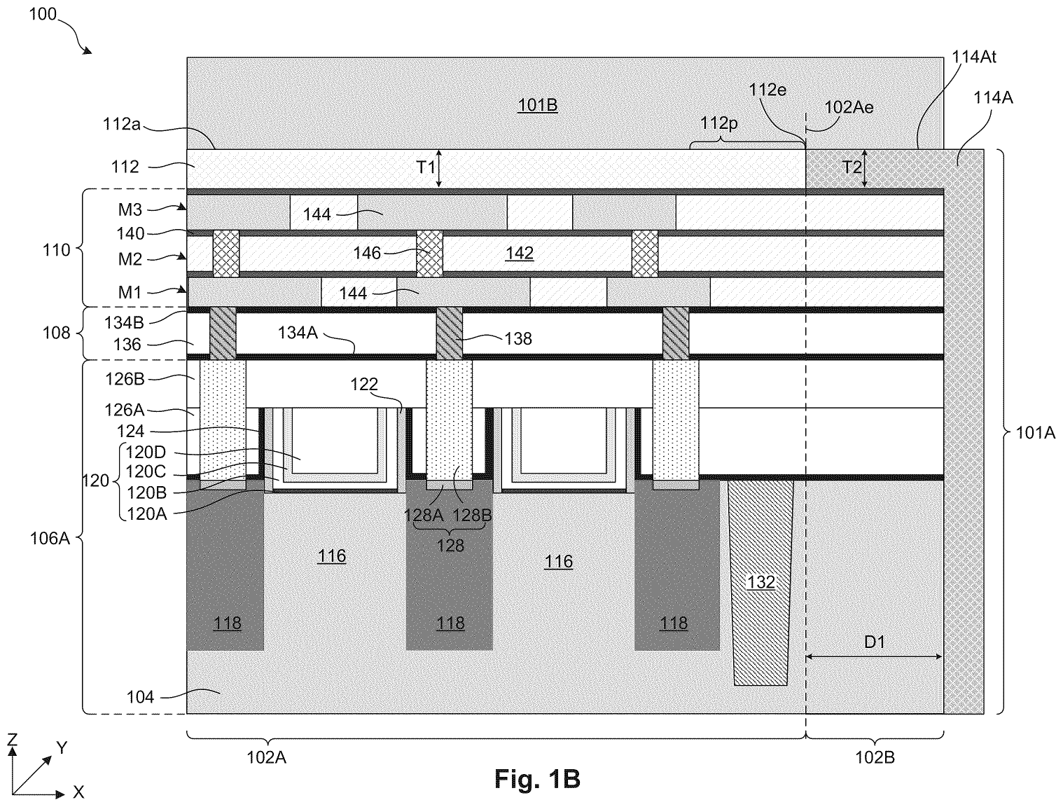

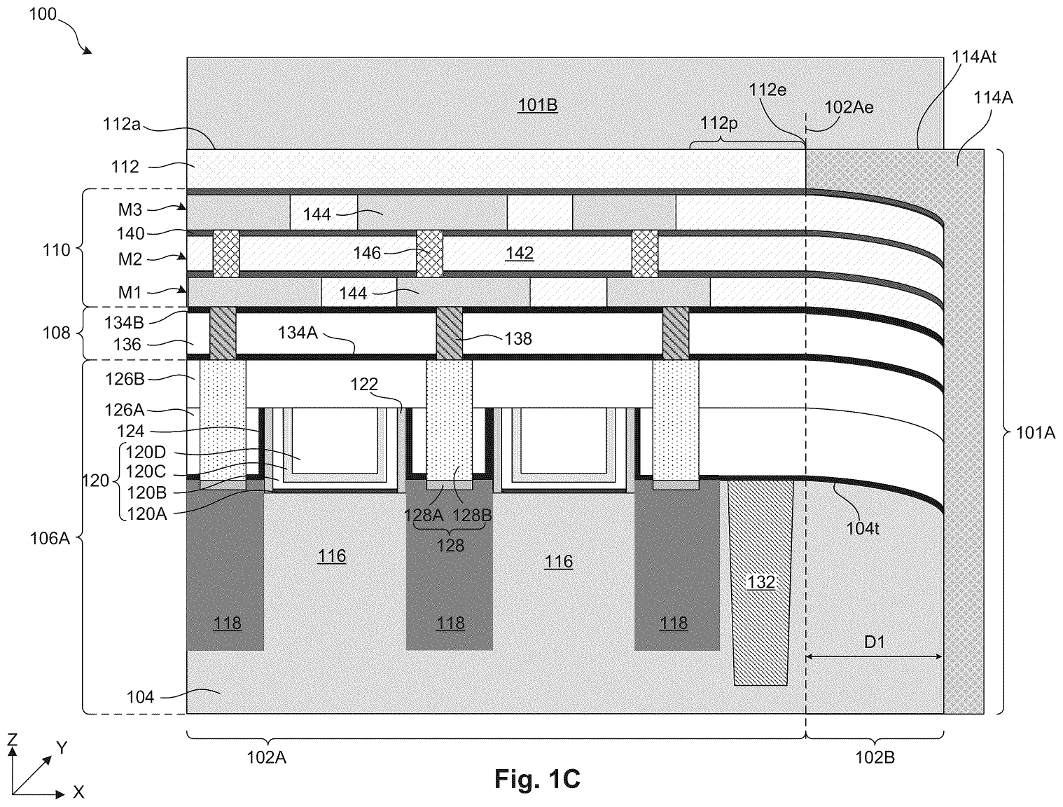

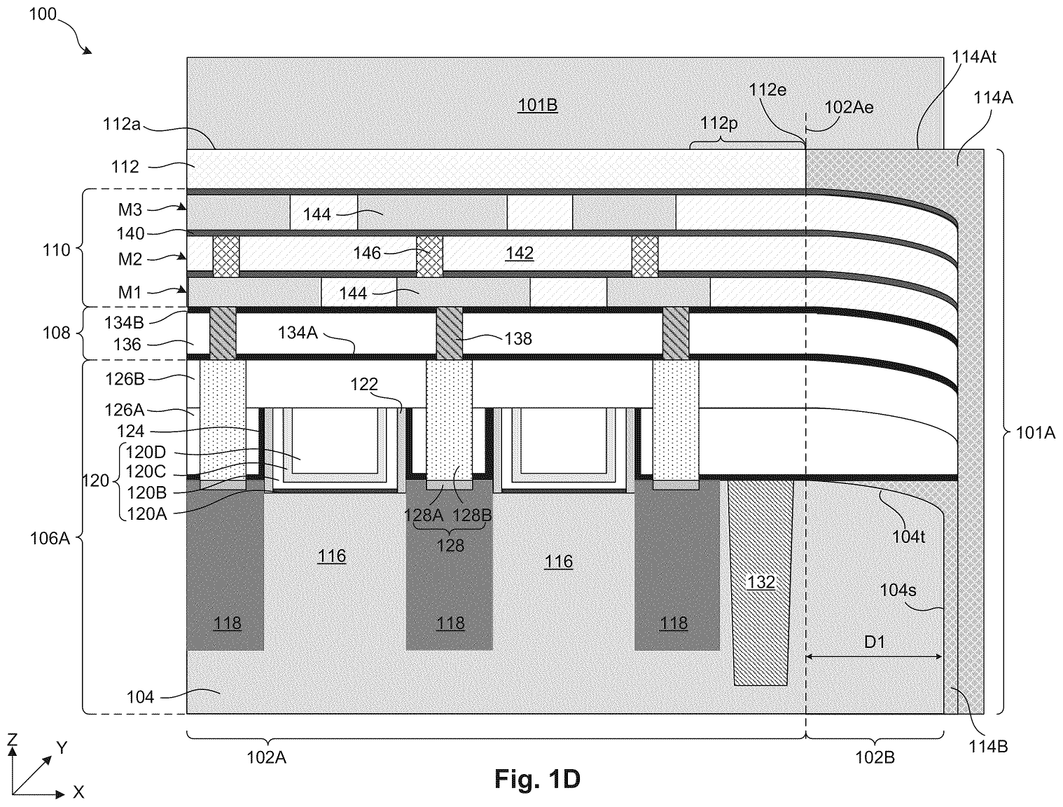

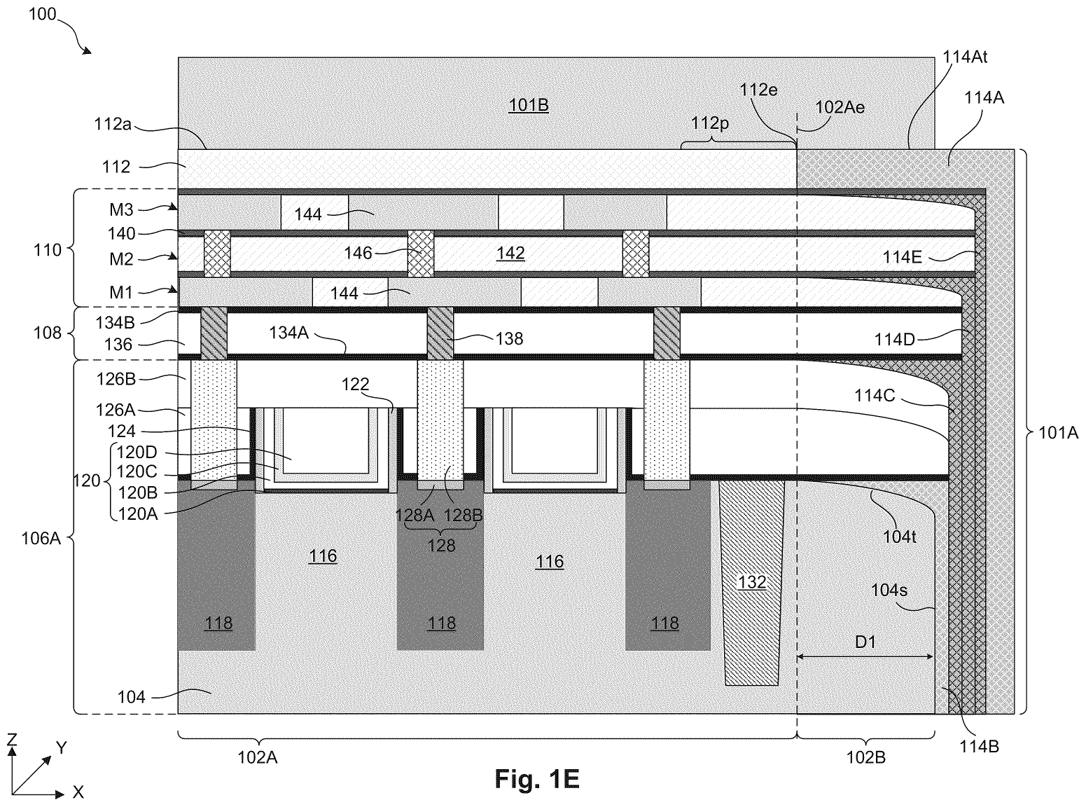

FIG. 1A illustrates an isometric view of a 3DIC 100, according to some embodiments. FIGS. 1B-1E illustrate different cross-sectional views of 3DIC 100 along line A-A of FIG. 1A, according to some embodiments. FIGS. 1B-1E illustrate cross-sectional views of FET 100 with additional structures that are not shown in FIG. 1A for simplicity. The discussion of elements with the same annotations applies to each other, unless mentioned otherwise.

Referring to FIGS. 1A-1E, in some embodiments, 3DIC 100 can include a first IC chip 101A and a second IC chip 101B stacked on top of first IC chip 101A. Though 3DIC 100 is shown to have two IC chips, 3DIC 100 can have any number of IC chips.

Referring to FIGS. 1A and 1B, in some embodiments, first IC chip 101A can include (i) a device region 102A (also referred to as a “functional region 102A”) and (ii) a peripheral region 102B adjacent to and surrounding device region 102A. FIG. 1B shows peripheral region 102B on one side of device region 102A and does not show peripheral region 102B surrounding device region 102A for simplicity. As described in detail below, in some embodiments, device region 102A can include electrically active devices and structures, and peripheral region 102B can include electrically inactive layers. In some embodiments, peripheral region 102B does not include electrically active devices and structures. In some embodiments, peripheral region 102B can extend a distance D1 of about 5 mm to about 10 mm from the edge of a substrate 104 of first IC chip 101A towards the center of substrate 104.

In some embodiments, first IC chip 101A can include (i) substrate 104, (ii) a device layer 106 disposed on substrate 104, (iii) a via layer 108 disposed on device layer 106, (iv) an interconnect structure 110 disposed on via layer 108, (v) a bonding layer 112 (also referred to as a “passivation layer 112”) disposed on interconnect structure 110, and (vi) a polish stop layer (PSL) 114A disposed on interconnect structure 110. First IC chip 101A can include other elements between interconnect structure 110 and bonding layer 112, such as conductive pads disposed on interconnect structure 110, a polymer layer disposed on the conductive pads, conductive vias disposed on the conductive pads, and a stress buffer layer disposed on the polymer layer, which are not shown for simplicity. In some embodiments, the structures in device layer 106, described below, can be referred to as “front-end-of-the-line (FEOL) structures.” In some embodiments, the structures in via layer 108, described below, can be referred to as “middle-end-of-the-line (MEOL) structures” or “middle-of-the-line (MOL) structures.” In some embodiments, the structures in interconnect structure 110, described below, can be referred to as “back-end-of-the-line (BEOL) structures.”

In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic).

Referring to FIGS. 1A and 1B, in some embodiments, bonding layer 112 can include a dielectric material, such as silicon oxide (SiO₂), silicon nitride (SiN), silicon oxynitride (SiON), silicon carbide (SiC), silicon carbon nitride (SiCN), silicon oxycarbon nitride (SiOCN), and metal oxide. Bonding layer 112 can be disposed on a portion of interconnect layer 110 in device region 102A and can be configured to mechanically bond first IC chip 101A to second IC chip 101B. The bonding reliability between first and second IC chips 101A and 101B can depend on the surface profile and/or the substantially planarized surface area dimension of a top surface 112a of bonding layer 112. The greater the surface planarity of top surface 112a and/or the larger the substantially planarized surface area dimension of top surface 112a, the higher is the bonding reliability between first and second IC chips 101A and 101B.

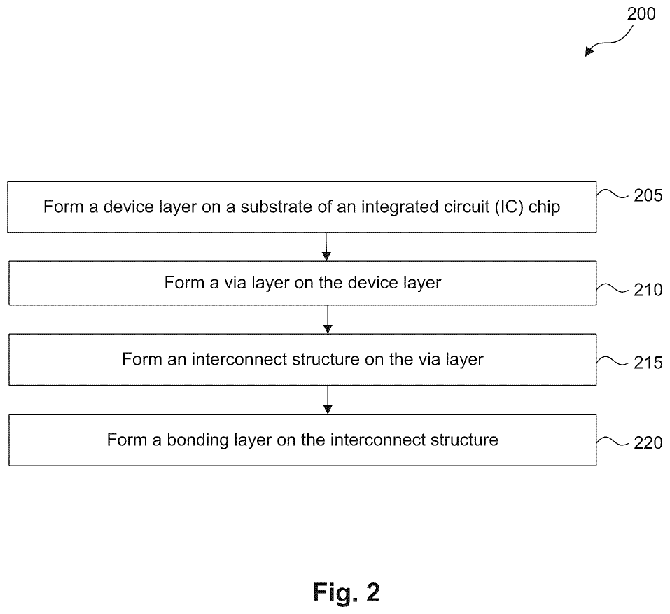

With the use of PSL 114A, a substantially planarized top surface 112a with no edge roll-off or negligible edge roll-off in edge portion 112p of bonding layer 112 at and/or near edge 102Ae of device region 102A can be formed, as shown in FIG. 1B. Top surface 112a can be substantially coplanar with a top surface 114At of PSL 114A and thickness T1 of bonding layer 112 can be substantially equal to thickness T2 of PSL 114. PSL 114A can eliminate or minimize the difference in the polishing rates of edge portion 112p and other portions (e.g., central portion) of bonding layer 112 due to higher concentration of polishing stress at and/or near edge 102Ae, as described below with reference to FIGS. 2-6. The surface height variation (also referred to as “topography variation”) achieved between edge 112e and center (not shown) of bonding layer 112 can be less than about 30 nm (e.g., about 1 nm to about 30 nm). Within this range of surface height variation, the entire surface area of top surface 112a or about 100% surface area of top surface 112a can be effectively used for bonding first and second IC chips 101A and 101B. Thus, with the use of PSL 114A, a larger surface area of bonding layer 112 can be effectively used for bonding IC chips compared to bonding layers formed without using PSL 114A.

In some embodiments, PSL 114A can include an oxide layer (e.g., SiO₂), a nitride layer (e.g., SiN), a carbide layer (e.g., SiC or SiCN), a metal layer (e.g., tantalum (Ta)), a metal oxide layer (e.g., tungsten oxide (WOₓ)), a metal nitride layer (e.g., tantalum nitride (TaN) or titanium nitride (TiN)), or a polysilicon layer. In some embodiments, PSL 114A can include a material different from the material of bonding layer 112. The material of PSL 114A can have a higher polishing resistance to a polishing chemical compared to that of the material of bonding layer 112. The higher polishing resistance can achieve a lower polishing rate for the material of PSL 114A during a polishing process (e.g., CMP process) compared to that achieved for the material of bonding layer 112, as described below with reference to FIGS. 2-6. In some embodiments, PSL 114A can include SiN if bonding layer 112 includes SiO₂ or metal oxide, and vice versa, to achieve a high polishing selectivity between PSL 114A and bonding layer 112. In some embodiments, PSL 114A can include polysilicon if bonding layer 112 includes SiO₂ to achieve a high polishing selectivity between PSL 114A and bonding layer 112.

In some embodiments, PSL 114A can include a horizontal portion and a vertical portion. The horizontal portion of PSL 114A can be disposed on entire top surface of the portion of interconnect structure 110 in peripheral region 102B. The vertical portion of PSL 114A can be disposed directly on outer sidewall of first IC chip 101A, which includes outer sidewalls of the portions of interconnect structure 110, via layer 108, device layer 106, and substrate 104 in peripheral region 102B. In some embodiments, PSL 114A can be formed with the horizontal portion of PSL 114A extending up to edge 102Ae of device region 102A and distance D1 of about 5 mm to about 10 mm from the edge of substrate 104 towards the center of substrate 104 for achieving the surface profile of bonding layer 112 discussed above.

Referring to FIGS. 1A and 1B, in some embodiments, device layer 106 can include finFETs 106A and 106B (also referred to as “FETs 106A and 106B”). The discussion of FET 106A applies to FET 106B, unless mentioned otherwise. Though device layer 106 is shown to have two FETs, device layer 106 can have any number of FETs. Device layer 106 can also include other active and/or passive devices, which are not shown for simplicity. In some embodiments, in addition to or instead of finFETs 106A and 106B, device layer 106 can include GAA FETs and/or MOSFETs, which are not shown for simplicity.

In some embodiments, FET 106A can include (i) a fin structure 116 disposed on substrate 104, (ii) source/drain (S/D) regions 118 disposed on fin structure 116, (iii) gate structures 120 disposed on fin structure 116, (iv) gate spacers 122 disposed on sidewalls of gate structures 112, (v) etch stop layers (ESLs) 124 disposed on S/D regions 118, (vi) interlayer dielectric (ILD) layers 126A and 126B disposed on ESLs 124, (vii) contact structures 128 disposed on S/D regions 118, (viii) shallow trench isolation (STI) regions 130 disposed on substrate 104, and (ix) isolation structure 132 disposed in fin structure 116. S/D regions 118 may refer to a source or a drain, individually or collectively dependent upon the context.

In some embodiments, fin structure 116 can include a material similar to substrate 104 and extend along an X-axis. Fin structure 116 can have elongated sides extending along an X-axis. In some embodiments, gate spacers 122, ESLs 124, ILD layers 126A and 126B, STI regions 130, and isolation structure 132 can include an insulating material, such as SiO₂, SiN, SiON, SiCN, SiOCN, and silicon germanium oxide (SiGeOₓ).

For n-type FET 106A, each S/D region 118 can include an epitaxially-grown semiconductor material, such as Si, and n-type dopants, such as phosphorus and other suitable n-type dopants. For p-type FET 106A, each S/D region 118 can include an epitaxially-grown semiconductor material, such as Si and SiGe, and p-type dopants, such as boron and other suitable p-type dopants.

In some embodiments, each gate structure 120 can include (i) an interfacial oxide (IL) layer 120A, (ii) a high-k (HK) gate dielectric layer 120B disposed on IL layer 120A, (iii) a work function metal (WFM) layer 120C disposed on HK gate dielectric layer 120B, and (iv) a gate metal fill layer 120D disposed on WFM layer 120C. In some embodiments, IL layer 120A can include SiO₂, SiGeOₓ, or germanium oxide (GeOₓ). In some embodiments, HK gate dielectric layer 120B can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, WFM layer 120C can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type FET 106A. In some embodiments, WFM layer 120C can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for p-type FET 106A. In some embodiments, gate metal fill layer 120D can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

In some embodiments, each contact structure 128 can include (i) a silicide layer 128A disposed on S/D region 118 and (ii) a contact plug 128B disposed on silicide layer 128A.

In some embodiments, each silicide layer 128A can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof for n-type FET 106A. In some embodiments, each silicide layer 122A can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof for p-type FET 106A. In some embodiments, each contact plug 128B can include conductive materials with low resistivity (e.g., resistivity of about 50 μΩ-cm or less), such as Co, W, Ru, Al, Mo, Ir, Ni, Osmium (Os), rhodium (Rh), other suitable conductive materials with low resistivity, and a combination thereof.

Isolation structure 132 is an electrically inactive structure and not electrically coupled to any power supplies and electrically isolated from other structures of FET 106A. In some embodiments, a top surface of isolation structure 132 can be substantially coplanar with a top surface of fin structure 116. In some embodiments, isolation structure 132 can have a tapered structure with the top surface having a width greater than a width of a bottom surface.

In some embodiments, via layer 108 can include (i) ESLs 134A and 134B, (ii) ILD layer 136 disposed between ESLs 134A and 134B, and (iii) vias 138 disposed in portions of ILD layer 136 and ESLs 134A and 134B in device region 102A. Via layer 108 does not have vias in peripheral region 102B. In some embodiments, via layer 108 can electrically connect FET 106A to interconnect structure 110 through vias 138. In some embodiments, vias 138 can include a conductive material, such as such as Ru, Co, Ni, Al, Mo, W, Ir, Os, Cu, and Pt. ILD layer 136 and ESLs 134A and 134B can include an insulating material, such as SiO₂, SiN, SiON, SiCN, SiOCN, and SiGeOₓ.

In some embodiments, interconnect structure 110 can be disposed on via layer 108. In some embodiments, interconnect structure 110 can include interconnect layers M1-M3. Though three interconnect layers M1-M3 are discussed with reference to FIG. 1B, interconnect structure 110 can have any number of interconnect layers. Each of interconnect layers M1-M3 can include an ESL 140 and an ILD layer 142. ESLs 140 can include a dielectric material, such as aluminum oxide (AlₓO_{y}), nitrogen doped silicon carbide (SiCN), and oxygen doped silicon carbide (SiCO) with a dielectric constant ranging from about 4 to about 10.

In some embodiments, ILD layers 142 can include a low-k (LK) or extra low-k (ELK) dielectric material with a dielectric constant lower than that of silicon oxide (e.g., dielectric constant between about 2 and about 3.7). The LK or ELK dielectric material can reduce parasitic capacitances between interconnect layers M1-M3. In some embodiments, the LK or ELK dielectric material can include silicon oxycarbide (SiOC), nitrogen doped silicon carbide (SiCN), silicon oxycarbon nitride (SiCON), or oxygen doped silicon carbide. In some embodiments, ILD layers 142 can include one or more layers of insulating carbon material with a low dielectric constant of less than about 2 (e.g., ranging from about 1 to about 1.9). In some embodiments, the one or more layers of insulating carbon material can include one or more fluorinated graphene layers with a dielectric constant ranging from about 1 to about 1.5, or can include one or more graphene oxide layers.

In some embodiments, the portion of interconnect structure 110 in device region 102A can include electrically active (i) conductive lines 144 in each of interconnect layers M1 and M3, and (ii) conductive vias 146 in interconnect layer M2. Conductive lines 144 and conductive vias 146 can be electrically connected to power supplies and/or active devices. The layout of conductive lines 144 and conductive vias 146 is exemplary and not limiting and other layout variations of conductive lines 144 and conductive vias 146 are within the scope of this disclosure. The routings (also referred to as “electrical connections”) between FET 106A and the portion of interconnect structure 106A in device region 102A are exemplary and not limiting. There may be routings between FET 106A and interconnect layers M1-M3 that are not visible in the cross-sectional views of FIG. 1B.

Each of conductive lines 144 can be disposed within ILD layer 142 and each of conductive vias 146 can be disposed within ILD layer 142 and a pair of ESLs 140 disposed on top and bottom surfaces of the corresponding ILD layer 142. Conductive vias 146 provide electrical connections between conductive lines 144 of adjacent interconnect layers. In some embodiments, conductive lines 144 can include electrically conductive material, such as Cu, Ru, Co, Mo, carbon nanotubes, graphene layers, and any other suitable conductive material. In some embodiments, conductive vias 146 can include an electrically conductive material, such as Cu, Ru, Co, Mo, a Cu alloy (e.g., Cu—Ru, Cu—Al, or copper-manganese (CuMn)), carbon nanotubes, graphene layers, and any other suitable conductive material. In some embodiments, conductive lines 144 and conductive vias 146 can include a metal liner (not shown) on which the conductive material is disposed. The metal liner can include a metal, such as tantalum, cobalt, and other suitable metals, or metal nitrides, such as titanium nitride, tantalum nitride, and other suitable metal nitrides. Conductive lines 144 and conductive vias 146 of one or more of interconnect layers M1-M3 can be single-damascene structures or dual-damascene structures.

FIG. 1C illustrates a different cross-sectional view of 3DIC along line A-A of FIG. 1A. The discussion of elements with the same annotations in FIGS. 1A, 1B, and 1C applies to each other, unless mentioned otherwise. In some embodiments, substrate 104 can have a beveled edge, and as a result, a top surface 104t of the portion of substrate 104 in peripheral region 102B can have a non-planar (e.g., curved) surface profile, unlike the planar surface profile of top surface in FIG. 1B. Due to the non-planar surface profile of top surface 104t in peripheral region 102B, the portions of device layer 106, via layer 108, and/or interconnect structure 110 formed on top surface 104t can follow the non-planar topography of top surface 104t and have non-planar top surface profiles. With the use of PSL 114A, the formation of bonding layer 112 with a non-planar top surface profile similar to the underlying layers can be prevented and a substantially planarized top surface 112a with no edge roll-off or negligible edge roll-off in edge portion 112p of bonding layer 112 can be formed, as discussed above with reference to FIG. 1B.

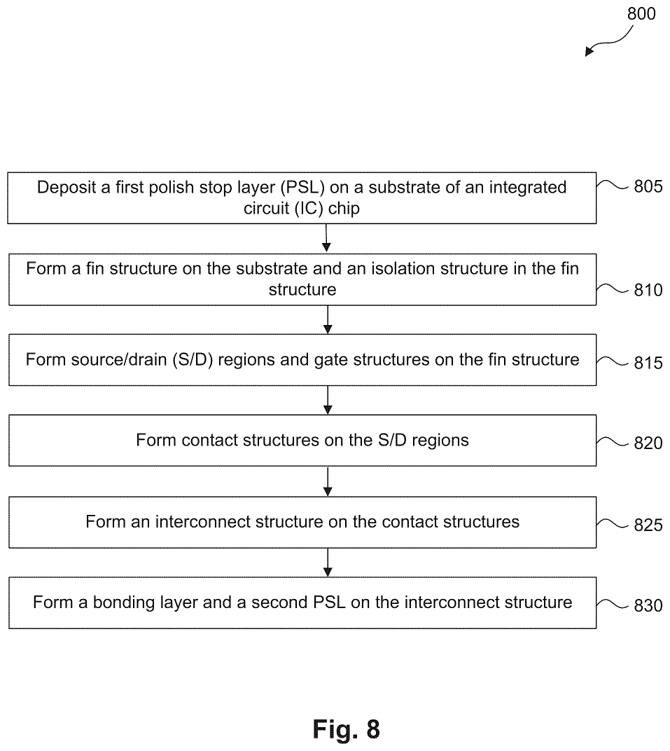

FIG. 1D illustrates a different cross-sectional view of 3DIC along line A-A of FIG. 1A. The discussion of elements with the same annotations in FIGS. 1A-1D applies to each other, unless mentioned otherwise. In some embodiments, first IC chip 101A can further include a PSL 114B disposed on top surface 104t and sidewall 104s of substrate 104. PSL 114B can prevent underlying substrate 104 from being polished during a polishing process performed during the formation of isolation structure 132, as described in detail below with reference to FIGS. 8-11. In the absence of PSL 114B, top surface 104t can be exposed to the polishing process and a portion of substrate 104 in peripheral region 102B can be removed. The damage to substrate 104 can also negatively impact the surface profiles of the overlying layers. In some embodiments, top surfaces of PSL 114B and isolation structure 132 can be substantially coplanar with each other.

In some embodiments, PSL 114B can include an oxide layer (e.g., SiO₂), a nitride layer (e.g., SiN), a carbide layer (e.g., SiC or SiCN), or a polysilicon layer. In some embodiments, PSL 114B can include a material different from the material of isolation structure 132. The material of PSL 114B can have a higher polishing resistance to a polishing chemical compared to that of the material of isolation structure 132. The higher polishing resistance can achieve a lower polishing rate for the material of PSL 114B during a polishing process (e.g., CMP process) compared to that achieved for the material of isolation structure 132, as described below with reference to FIGS. 8-11. In some embodiments, PSL 114B can include SiN if isolation structure 132 includes SiO₂, and vice versa, to achieve a high polishing selectivity between PSL 114B and isolation structure 132. In some embodiments, PSL 114B can include polysilicon if isolation structure 132 includes SiO₂ to achieve a high polishing selectivity between PSL 114B and isolation structure 132. In some embodiments, the materials of PSL 114A and 114B can be similar to or different from each other.

Unlike PSL 114A of FIG. 1B, PSL 114A in FIG. 1D is not disposed directly on outer sidewall of substrate 104, but is directly disposed on outer sidewall of PSL 114B. In addition, unlike ESL 124 of FIGS. 1B and 1C, ESL 124 is not disposed directly on the portion of substrate 104 in peripheral region 102B, but is directly disposed on top surface of PSL 114B.

FIG. 1E illustrates a different cross-sectional view of 3DIC along line A-A of FIG. 1A. The discussion of elements with the same annotations in FIGS. 1A-1E applies to each other, unless mentioned otherwise. In some embodiments, first IC chip 101A can further include PSLs 114C, 114D, and 114E. PSL 114C can be disposed directly on top surface portion of ILD layer 126B in peripheral region 102A and on outer sidewalls of ILD layers 126A and 128, ESL 124, and PSL 114B. PSL 114D can be disposed directly on top surface portion of ILD layer 142 of interconnect layer M1 in peripheral region 102A and on outer sidewalls of ILD layers 142 and 136, and PSL 114C. PSL 114E can be disposed directly on top surface portion of ILD layer 142 of interconnect layer M3 in peripheral region 102A and on outer sidewalls of ILD layers 142 of interconnect layers M2 and M3, and PSL 114D. Similar to PSL 114B, PSLs 114C, 114D, and 114E can prevent underlying layers from being polished. PSL 114C can prevent underlying ILD layer 126B from being polished during the formation of contact plugs 128B, as described in detail below with reference to FIGS. 8 and 12-14. Similarly, PSLs 114D and 114E can prevent underlying ILD layers 142 from being polished during the formation of conductive lines 144, as described in detail below with reference to FIGS. 8 and 12-15.

In some embodiments, PSL 114C can include an oxide layer (e.g., SiO₂), a metal oxide layer (e.g., WOₓ), or a metal nitride layer (e.g., TaN). In some embodiments, PSL 114C can include a material different from the material of contact plugs 128B. The material of PSL 114C can have a higher polishing resistance to a polishing chemical compared to that of the material of contact plugs 128B. The higher polishing resistance can achieve a lower polishing rate for the material of PSL 114C during a polishing process (e.g., CMP process) compared to that achieved for the material of contact plugs 128B, as described below with reference to FIGS. 8 and 12-14. In some embodiments, PSL 114C can include SiO₂ or WOₓ if contact plugs 128B include tungsten (W) to achieve a high polishing selectivity between PSL 114C and contact plugs 128B. In some embodiments, PSL 114C can include SiO₂ or TaN if contact plugs 128B include cobalt (Co) to achieve a high polishing selectivity between PSL 114C and contact plugs 128B.

In some embodiments, PSLs 114D and 114E can include a an oxide layer (e.g., SiO₂), a metal layer (e.g., Ta), or a metal nitride layer (e.g., TaN). In some embodiments, PSLs 114D and 114E can include materials different from the material of conductive lines 144. The materials of PSLs 114D and 114E can have a higher polishing resistance to a polishing chemical compared to that of the material of conductive lines 144. The higher polishing resistance can achieve a lower polishing rate for the materials of PSLs 114D and 114E during a polishing process (e.g., CMP process) compared to that achieved for the material of conductive lines, as described below with reference to FIGS. 8 and 12-15. In some embodiments, PSLs 114D and 114E can include SiO₂, Ta, or TaN if contact plugs 128B include copper (Cu) to achieve a high polishing selectivity between PSL 114D and conductive lines 144 and between PSL 114E and conductive lines 144. In some embodiments, the materials of PSLs 114D and 114E can be similar to each other, and different from the materials of PSLs 114A, 114B, and/or 114C.

Unlike PSL 114A of FIG. 1B, PSL 114A in FIG. 1E is not disposed directly on outer sidewall of substrate 104, but is directly disposed on outer sidewall of PSL 114E. In addition, (i) unlike ESL 134A of FIGS. 1B-1D, ESL 134A is not disposed directly on the portion of ILD layer 126B in peripheral region 102B, but is directly disposed on top surface of PSL 114C, (ii) unlike ESL 140 of interconnect layer M1 of FIGS. 1B-1D, ESL 140 is not disposed directly on the portion of ILD layer 142 in peripheral region 102B, but is directly disposed on top surface of PSL 114D, and (iii) unlike ESL 140 of interconnect layer M3 of FIGS. 1B-1D, ESL 140 is not disposed directly on the portion of ILD layer 142 in peripheral region 102B, but is directly disposed on top surface of PSL 114E.

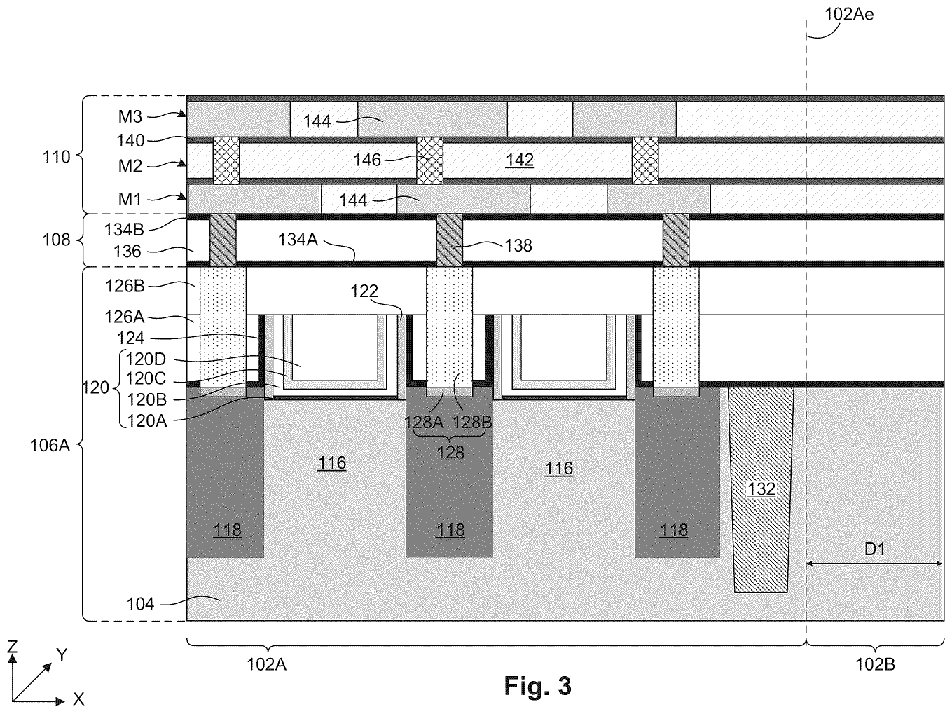

FIG. 2 is a flow diagram of an example method 200 for fabricating 3DIC 100 with a cross-sectional view of FIG. 1B, according to some embodiments. For illustrative purposes, the operations illustrated in FIG. 2 will be described with reference to the example fabrication process for fabricating 3DIC 100 as illustrated in FIGS. 3-7. FIGS. 3-7 are cross-sectional views of 3DIC 100 along line A-A of FIG. 1A at various stages of fabrication, according to some embodiments. Operations can be performed in a different order or not performed depending on specific applications. It should be noted that method 200 may not produce a complete 3DIC 100. Accordingly, it is understood that additional processes can be provided before, during, and after method 200, and that some other processes may only be briefly described herein. Elements in FIGS. 3-7 with the same annotations as elements in FIGS. 1A and 1B are described above.

Referring to FIG. 2, in operation 205, a device layer is formed on a substrate of an IC chip. For example, as described with reference to FIG. 3, device layer 106 is formed on substrate 104 of first IC chip 101A. The formation of device layer 106 can include sequential operations of (i) forming fin structure 116 on substrate 104, (ii) forming S/D regions 118 on fin structure 116, (iii) forming gate structures 120 on fin structure 116, (iv) depositing ESL 124 on S/D regions 118, (v) depositing ILD layer 126A on ESL 124, (vi) depositing ILD layer 126B on ILD layer 126A, and (vii) forming contact structures 128 on S/D regions 118 and in ILD layers 126A and 126B.

Referring to FIG. 2, in operation 210, a via layer is formed on the device layer. For example, as described with reference to FIG. 3, via layer 108 is formed on device layer 106. The formation of device layer 106 can include sequential operations of (i) depositing ESL 134A on device layer 106, (ii) depositing ILD layer 136 on ESL 134A, and (iii) forming vias 138 on contact structures 128 and in ESL 134A and ILD layer 136.

Referring to FIG. 2, in operation 215, an interconnect structure is formed on the via layer. For example, as described with reference to FIG. 3, interconnect structure 110 is formed on via layer 108. The formation of interconnect structure 110 can include forming conductive lines 144 and conductive vias 146 in a single damascene process or in a dual damascene process.

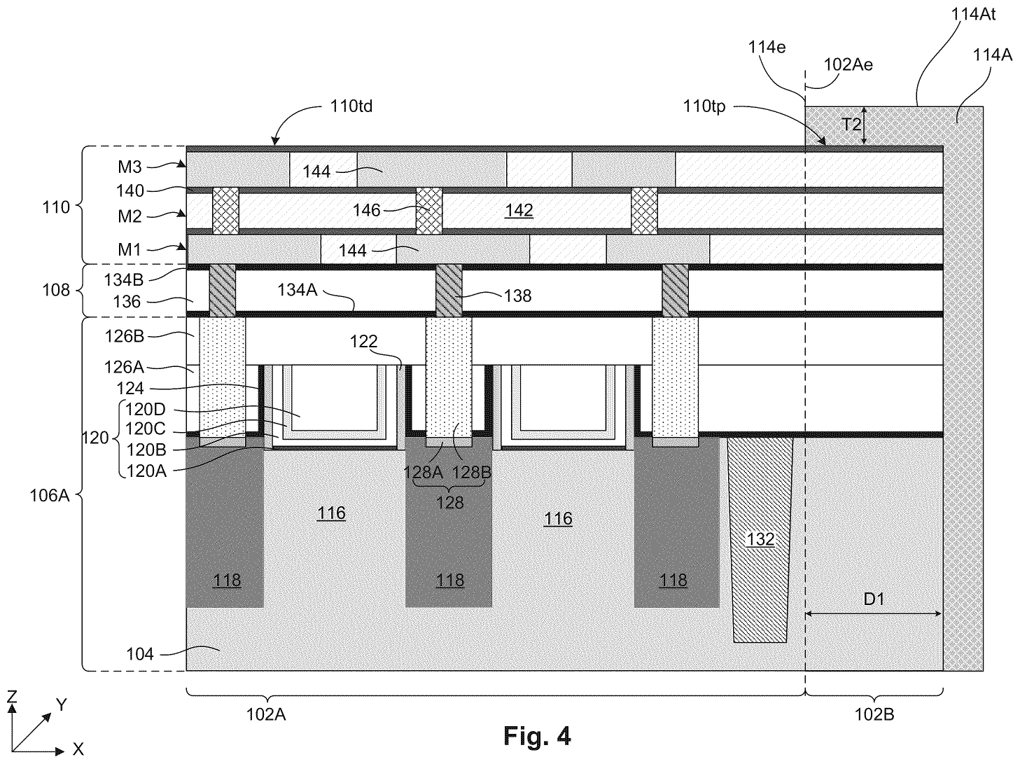

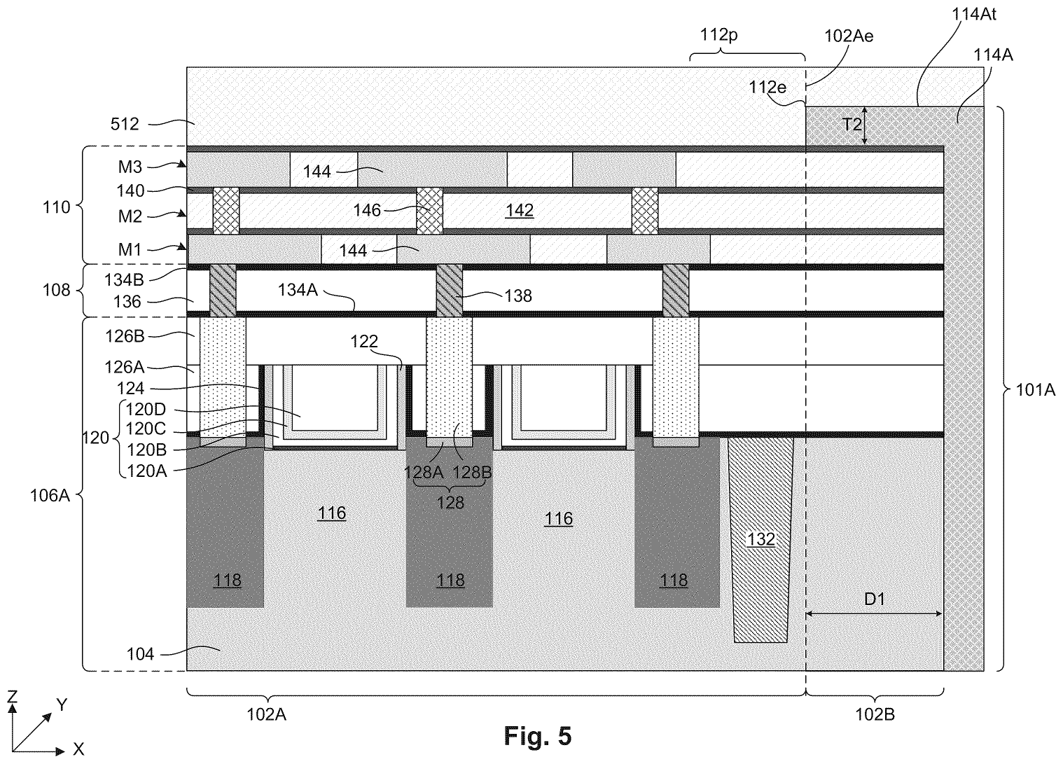

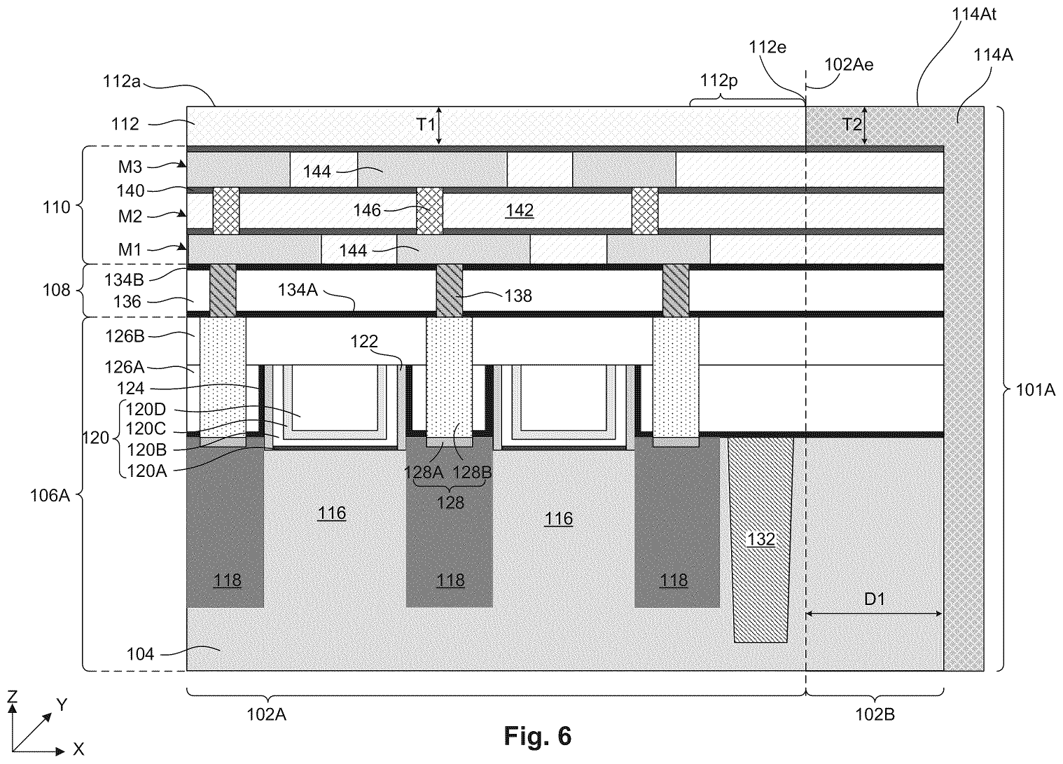

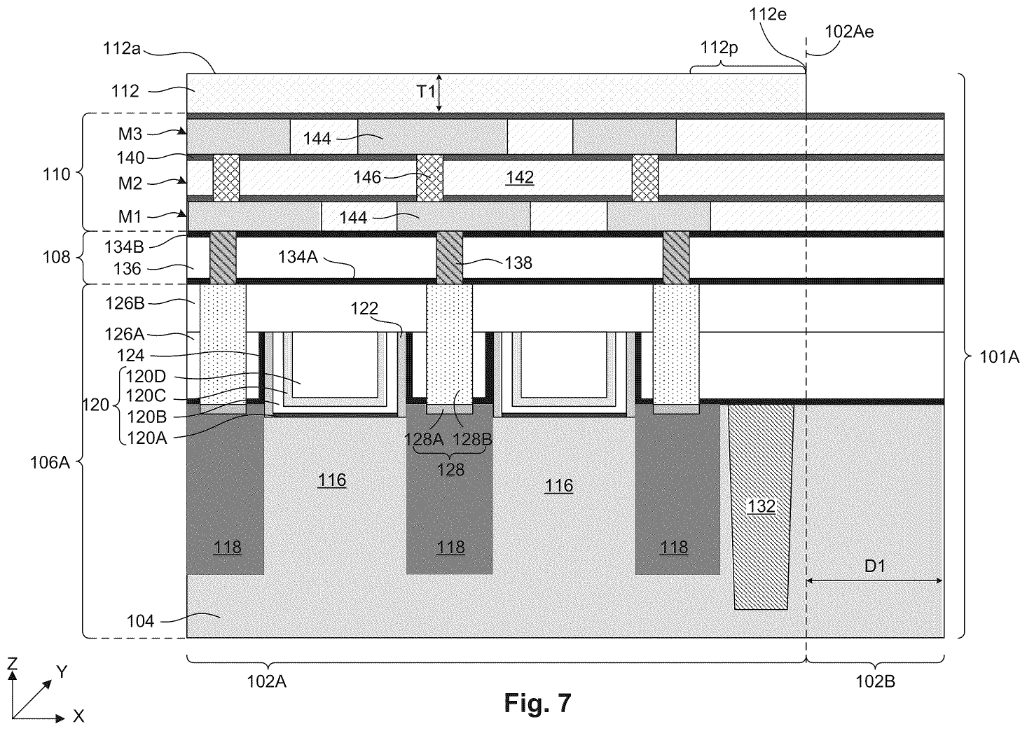

Referring to FIG. 2, in operation 220, a bonding layer is formed on the interconnect structure. For example, as described with reference to FIGS. 4-7, bonding layer 112 is formed on the portion of interconnect structure 110 in device region 102A. The formation of bonding layer 112 can include sequential operations of (i) masking (not shown) top surface portion 110td of interconnect structure 110 in device region 102A, (ii) depositing PSL 114A on top surface portion 110tp of interconnect structure in peripheral region 102B and on outer sidewalls of interconnect structure 110, via layer 108, device layer 106, and substrate 104, as shown in FIG. 4, (iii) depositing a layer 512 having the material of bonding layer 112 on the portion of interconnect structure 110 in device region 102A and on top surface 114At of PSL 114A, as shown in FIG. 5, (iv) performing a CMP process on layer 512 to form bonding layer 112 with top surface 112a substantially coplanarized with top surface 114At of PSL 114A, as shown in FIG. 6, and (v) performing a bonding process on bonding layer 112 to bond second IC chip 101B to bond first IC chip 101A and form the structure of FIG. 1B. In some embodiments, prior to bonding second IC chip 101B to first IC chip 101A, PSL 114A can be removed to form the structure of FIG. 7.

In some embodiments, masking top surface portion 110td can include patterning a masking layer (e.g., a photoresist layer; not shown) directly on top surface portion 110td or placing a metal plate (not shown) at a distance above the structure of FIG. 3 to cover top surface portion 110td during the deposition of PSL 114A. In some embodiments, the metal plate can be a part of the deposition chamber used for the deposition of PSL 114A.

In some embodiments, PSL 114A can be deposited with thickness T2 of about 100 nm to about 5 μm in a plasma enhanced chemical vapor deposition (PECVD) process using precursors and reaction gases at a deposition temperature of about 100° C. to about 400° C. and a radio frequency of about 10 MHz to about 15 MHz. In some embodiments, PSL 114A can be deposited with a greater thickness range of about 100 nm to about 20 μm in a physical vapor deposition (PVD) process (e.g., sputtering, e-beam, evaporative, plasma-assisted ion plating, etc.) using precursors and reaction gases at a deposition temperature of about room temperature to about 400° C. The deposition temperature is maintained at or below 400° C. to prevent thermal damages to the layers and/or structures in interconnect structure 110, via layer 108, and/or device layer 106. In some embodiments, reaction gases used in PECVD process can be silane (SiH₄), disilane (Si₂H₆), methane (CH₄), acetylene (C₂H₂), ammonia (NH₃), or a mixture of nitrogen and hydrogen. In some embodiments, reaction gases used in the PVD process can be argon, nitrogen, and hydrogen.

In some embodiments, the polishing chemical used in the CMP process can have a higher polishing selectivity for the material of layer 512 than the material of PSL 114A to achieve a higher polish rate on layer 512 than that on top surface 114At of PSL 114A. Due to the lower polish rate on PSL 114A, a negligible amount of PSL 114A may be removed without forming any edge roll-off region on PSL 114A when the portion of layer 512 on PSL 114A is removed and top surface 114At is exposed to the polishing process. As a result, when the portion of layer 512 in device region 102A is polished to thickness T1 (substantially equal to thickness T2), PSL 114A can prevent edge portion 112p from being over-polished to a thickness less than thickness T1 and can prevent the formation of edge roll-off in edge portion 112p.

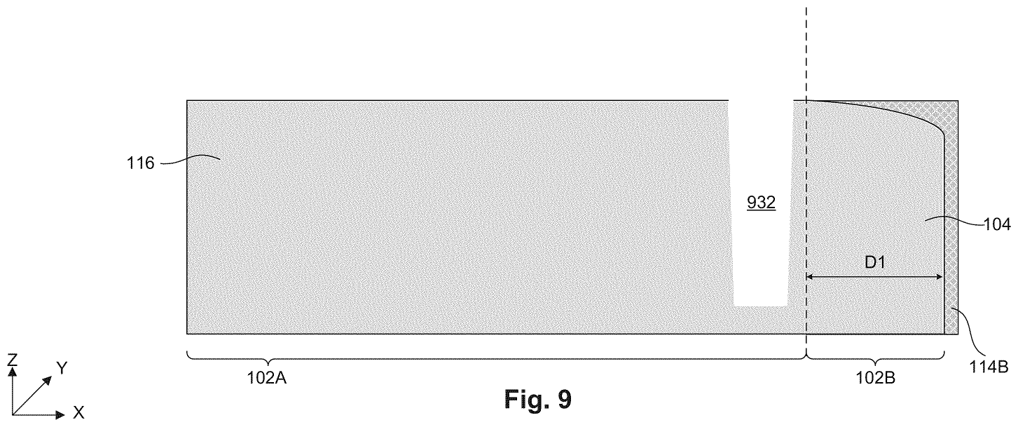

FIG. 8 is a flow diagram of an example method 800 for fabricating 3DIC 100 with cross-sectional views of FIG. 1E, according to some embodiments. For illustrative purposes, the operations illustrated in FIG. 8 will be described with reference to the example fabrication process for fabricating 3DIC 100 as illustrated in FIGS. 9-16. FIGS. 9-16 are cross-sectional views of 3DIC 100 along line A-A of FIG. 1A at various stages of fabrication, according to some embodiments. Operations can be performed in a different order or not performed depending on specific applications. It should be noted that method 800 may not produce a complete 3DIC 100. Accordingly, it is understood that additional processes can be provided before, during, and after method 800, and that some other processes may only be briefly described herein. Elements in FIGS. 9-16 with the same annotations as elements in FIGS. 1A-1E are described above.

Referring to FIG. 8, in operation 805, a first PSL is deposited on a substrate of an IC chip. For example, as described with reference to FIG. 9, PSL 114B is deposited on the portion of substrate 104 in peripheral region 102B. The deposition process for PSL 114B can be similar to that described above for PSL 114A, except the deposition temperature can be higher than that used for PSL 114A. In some embodiments, the deposition temperature for PSL 114B can be about 100° C. to about 600° C. Prior to depositing PSL 114B, the portion of substrate 104 in device region 102A can be masked in a manner similar to that described in operation 220 of FIG. 2.

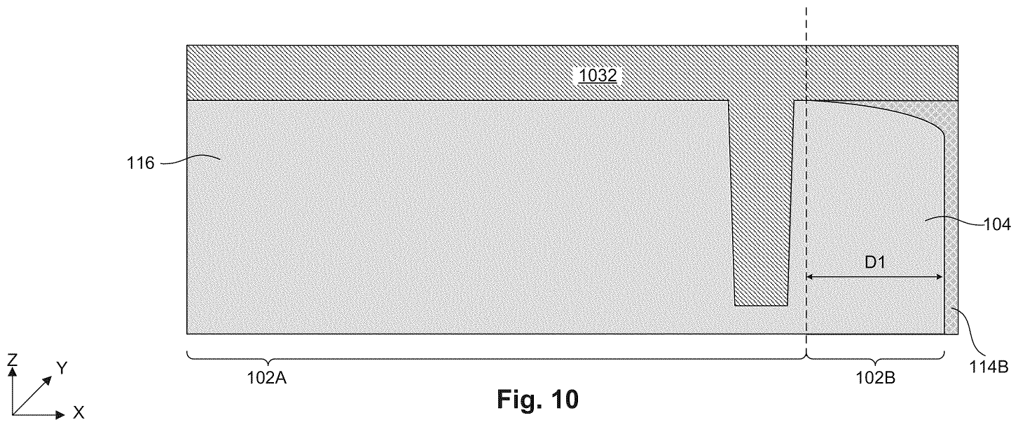

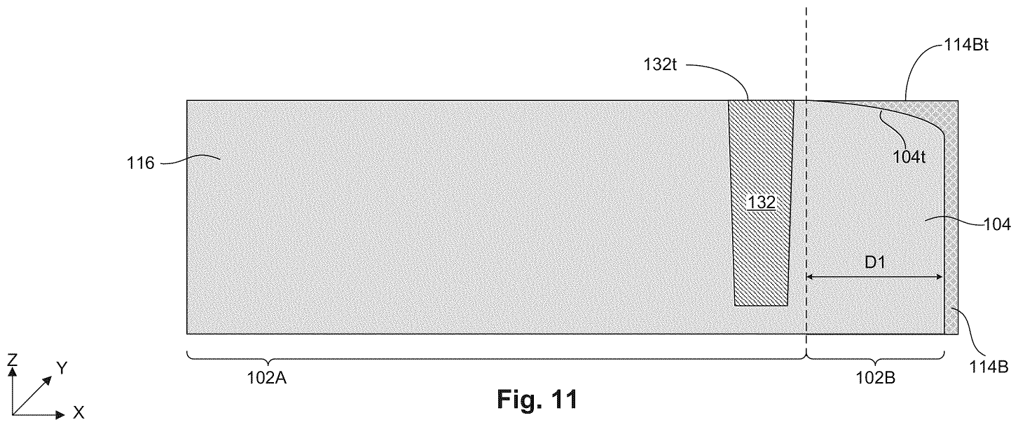

Referring to FIG. 8, in operation 810, a fin structure is formed on the substrate and an isolation structure is formed in the fin structure. For example, as described with reference to FIGS. 9-11, fin structure 116 is formed on the portion of substrate 104 in device region 102A and isolation structure 132 is formed in fin structure 116. The formation of isolation structure 132 can include sequential operations of (i) forming a trench 932 in fin structure 116, as shown in FIG. 9, (ii) depositing a layer 1032 having the material of isolation structure 132 in trench 932 and on fin structure 116 and PSL 114B, as shown in FIG. 10, and (iii) performing a CMP process on layer 1032 to form isolation structure 132 with top surface 132t substantially coplanarized with top surface 114Bt of PSL 114B, as shown in FIG. 11.

In some embodiments, the polishing chemical used in the CMP process can have a higher polishing selectivity for the material of layer 1032 than the material of PSL 114B to achieve a higher polish rate on layer 1032 than that on top surface 114Bt of PSL 114B. Due to the lower polish rate on PSL 114B, a negligible amount of PSL 114B may be removed when the portion of layer 1032 on PSL 114B is removed and top surface 114Bt is exposed to the polishing process. As a result, PSL 114B can prevent top surface 104t of the portion of substrate 104 in peripheral region 102B from being polished during the CMP process.

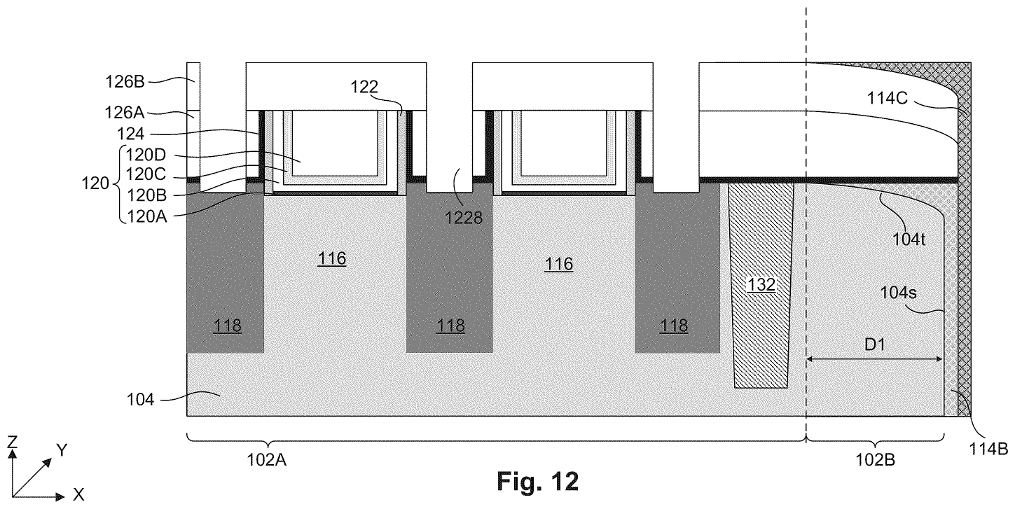

Referring to FIG. 8, in operation 815, S/D regions and gate structures are formed on the fin structure. For example, as described with reference to FIG. 12, S/D regions 118 and gate structures 120 can be formed on fin structure 116. Following the formation of S/D regions ESL 124 and ILD layers 126A and 126B can be formed.

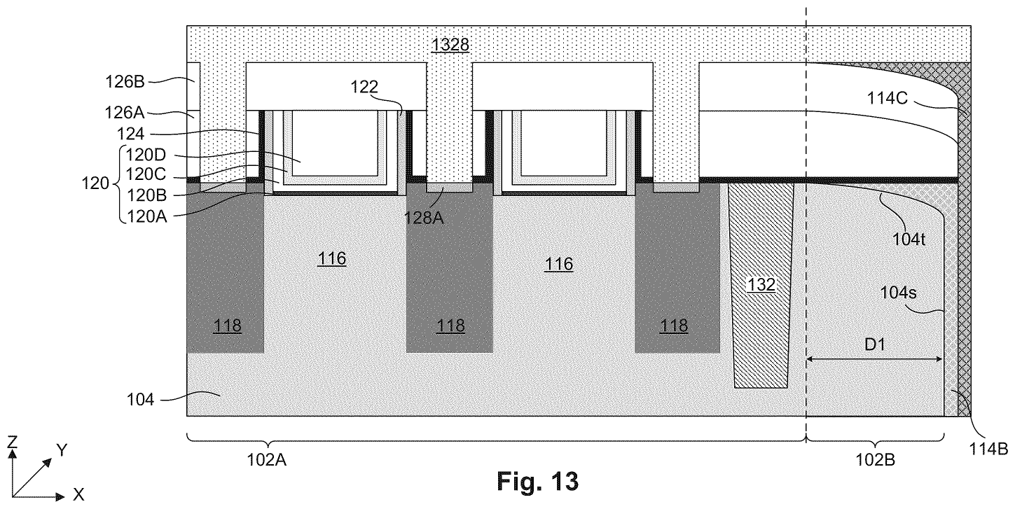

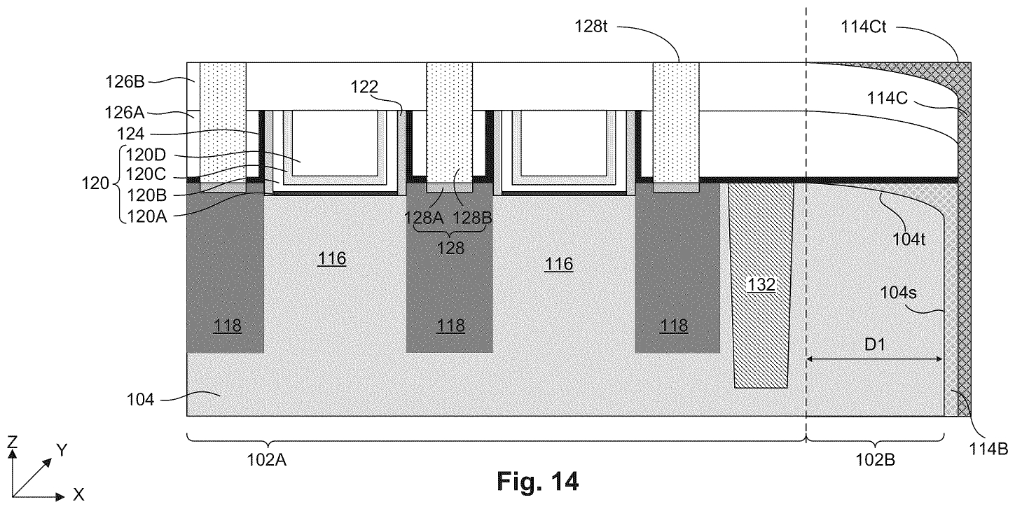

Referring to FIG. 8, in operation 820, contact structures are formed on S/D regions. For example, as described with reference to FIGS. 12-14, contact structures 128 are formed on S/D regions 118 and through ESL 124 and ILD layers 126A and 126B. The formation of contact structures 128 can include sequential operations of (i) depositing PSL 114C on the portion of ILD layer 126B in peripheral region 102B and on outer sidewalls of ILD layers 126A and 126B, ESL 124, and PSL 114B, as shown in FIG. 12, (ii) forming contact openings 1228 in ILD layers 126A and 126B and ESL 124, as shown in FIG. 12, (iii) forming silicide layers 128A on S/D regions 118 in contact openings 1228, as shown in FIG. 13, (iv) depositing a layer 1328 having the material of contact plugs 128B in contact openings 1228 and on ILD layer 126B and PSL 114C, as shown in FIG. 13, and (v) performing a CMP process on layer 1338 to form contact plugs 128B with top surface 128t substantially coplanarized with top surface 114Ct of PSL 114C, as shown in FIG. 14.

The deposition process for PSL 114C can be similar to that described above for PSL 114A, except the deposition temperature can be higher that used for PSL 114A. In some embodiments, the deposition temperature for PSL 114C can be about 100° C. to about 550° C. Prior to depositing PSL 114C, the portion of ILD layer 126B in device region 102A can be masked in a manner similar to that described in operation 220 of FIG. 2. In some embodiments, the polishing chemical used in the CMP process can have a higher polishing selectivity for the material of layer 1338 than the material of PSL 114C to achieve a higher polish rate on layer 1338 than that on top surface 114Ct of PSL 114C. Due to the lower polish rate on PSL 114C, a negligible amount of PSL 114C may be removed when the portion of layer 1338 on PSL 114C is removed and top surface 114Ct is exposed to the polishing process. As a result, PSL 114C can prevent a top surface of the portion of ILD layer 126B in peripheral region 102B and underlying layers from being polished during the CMP process.

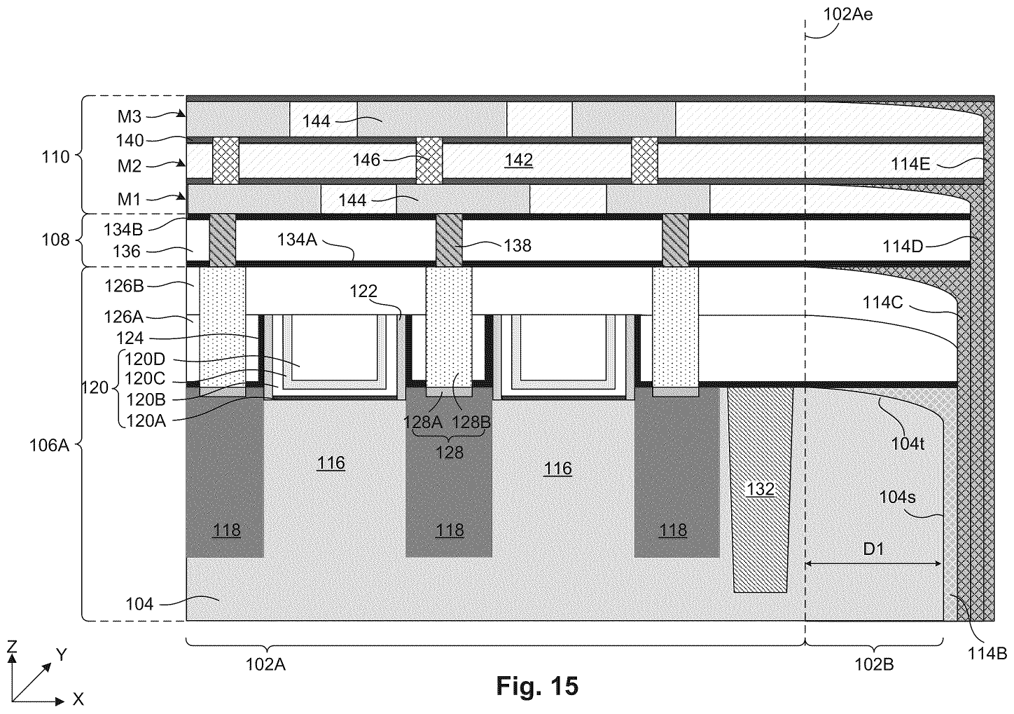

Referring to FIG. 8, in operation 825, an interconnect structure is formed on the contact structures. For example, as described with reference to FIG. 15, interconnect structure 110 with PSLs 114D and 114E can be formed on contact structures 128. In some embodiments, conductive lines 144 and PSLs 114D and 114E in interconnect layers M1 and M3 can be formed in a manner similar to that described for the formation of contact structures 128 in operation 820 of FIG. 8. Via layer 108 can be formed on contact structures 128 prior to the formation of interconnect structure 110.

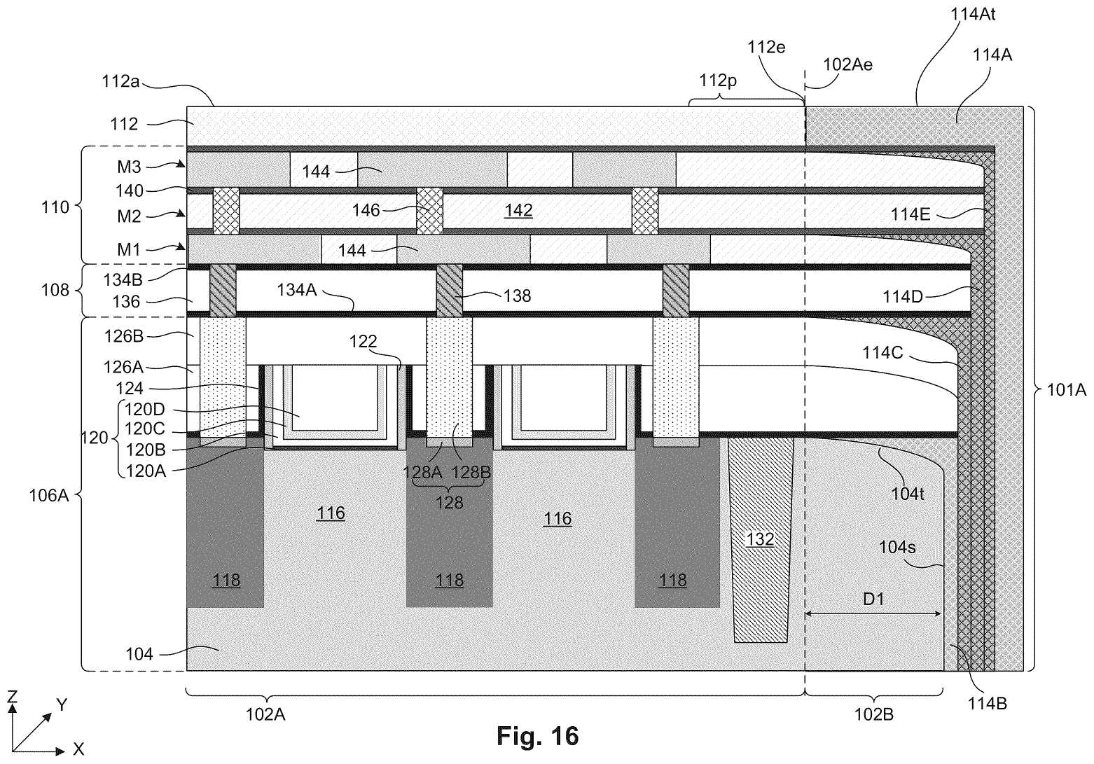

Referring to FIG. 8, in operation 830, a bonding layer and a second PSL is formed on the interconnect structure. For example, as described with reference to FIG. 16, bonding layer 112 and PSL 114A is formed on interconnect structure 110. The formation of bonding layer 112 and PSL 114A can be similar to that described in operation 220 of FIG. 2.

In some embodiments, the structure of FIG. 1C can be formed using method 800 with additional operations of (i) removing PSL 114B after the formation of isolation structure 132 in operation 810 and prior to the formation of S/D regions 118 in operation 815, (ii) removing PSL 114C after the formation of contact structures 128 in operation 820 and prior to the formation of via layer 108 in operation 825, and (iii) removing PSLs 114D and 114E after the formation of conductive lines 144 in operation 825 and prior to the formation of PSL 114A in operation 830.

In some embodiments, the structure of FIG. 1D can be formed using method 800 with additional operations of (i) removing PSL 114C after the formation of contact structures 128 in operation 820 and prior to the formation of via layer 108 in operation 825, and (ii) removing PSLs 114D and 114E after the formation of conductive lines 144 in operation 825 and prior to the formation of PSL 114A in operation 830.

The present disclosure provides example PSLs (e.g., PSL 114A) in IC chips (e.g., first IC chip 101A) and methods of forming the PSLs to form bonding layers (e.g., bonding layer 112) with substantially planar surface profiles and/or with minimized surface height variations (e.g. about 1 nm to about 30 nm) from centers to edges of the bonding layers. The PSL can prevent or minimize edge roll-off of the bonding layer at and/or near edges of device regions in the IC chip to eliminate or minimize the surface height variation from the center to the edge of the bonding layer and increase the dimension of substantially planarized surface areas of the bonding layer. Increasing the substantially planarized surface area dimensions can increase the bonding regions of the IC chips and improve the bonding interfaces between the stacked IC chips (e.g., first and second IC chips 101A and 101B) in 3DICs (e.g., 3DIC 100), thus improving the bonding reliability of the 3DICs.

In some embodiments, with the use of PSL, the bonding layer can be formed with a surface height variation of about 1 nm to about 30 nm from the center to the edges of the bonding layer. In some embodiments, the PSL can be formed in the peripheral regions (e.g., peripheral region 102A) of the IC chip prior to forming the bonding layer in the device regions (e.g., device region 102A) of the IC chip. The PSL can include a material with a higher polishing resistance than that of the material of the bonding layer. The highly polish resistant PSL can prevent or minimize the roll-off of the bonding layer at and/or near the edges of the devices regions during a polishing process (e.g., CMP process). The edge roll-off of the bonding layer can be due to a higher concentration of polishing stress at and/or near the edges of the device regions compared to the centers of the device regions. The edge roll-off of the bonding layer can also be due to the formation of the bonding layer on non-planar surfaces of underlying layers in the peripheral regions. The non-planar surfaces of the underlying layers can be due to the formation of the underlying layers on beveled surfaces in the peripheral regions of the substrate of the IC chip.

In some embodiments, a method includes forming a first IC chip having a device region and a peripheral region. Forming the first IC chip includes forming a device layer on a substrate, forming an interconnect structure on the device layer, depositing a first dielectric layer on a first portion of the interconnect structure in the peripheral region, depositing a second dielectric layer on the first dielectric layer and on a second portion of the interconnect structure in the device region, and performing a polishing process on the second dielectric layer to substantially coplanarize a top surface of the second dielectric layer with a top surface of the first dielectric layer. The method further includes performing a bonding process on the second dielectric layer to bond a second IC chip to the first IC chip.

In some embodiments, a method includes depositing a first dielectric layer on a first portion of a substrate in a peripheral region of an IC chip, forming a fin structure on a second portion of the substrate in a device region of the IC chip, forming a trench in the fin structure, depositing a second dielectric layer in the trench and on top surfaces of the fin structure and the first dielectric layer, performing a polishing process on the second dielectric layer to substantially coplanarize a top surface of the second dielectric layer with the top surface of the first dielectric layer, forming a S/D region on the fin structure, and depositing an ILD layer on the S/D region and on the first dielectric layer.

In some embodiments, a semiconductor structure includes a first IC chip having a device region and a peripheral region. The first IC chip includes a substrate, a device layer disposed on the substrate, an interconnect structure disposed on the device layer, a nitride layer disposed on a first portion of the interconnect structure in the peripheral region, and an oxide layer disposed on a second portion of the interconnect structure in the device region. A top surface of the oxide layer is substantially planarized with a top surface of the nitride layer. The semiconductor structure further includes a second IC chip disposed on the oxide layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first integrated circuit (IC) chip comprising a device region and a peripheral region, wherein forming the first IC chip comprises:
forming a device layer on a substrate,
forming an interconnect structure on the device layer,
depositing a first dielectric layer on a first portion of the interconnect structure in the peripheral region,
depositing a second dielectric layer on the first dielectric layer and on a second portion of the interconnect structure in the device region, and
performing a polishing process on the second dielectric layer to substantially coplanarize a top surface of the second dielectric layer with a top surface of the first dielectric layer; and
performing a bonding process on the second dielectric layer to bond a second IC chip to the first IC chip.

2. The method of claim 1, further comprising masking the second portion of the interconnect structure prior to depositing the first dielectric layer.

3. The method of claim 1, wherein depositing the first dielectric layer comprises depositing a nitride layer.

4. The method of claim 1, wherein depositing the second dielectric layer comprises depositing an oxide layer.

5. The method of claim 1, wherein performing the polishing process comprises performing chemical mechanical polishing with a polishing chemical that has a higher polishing selectivity for a material of the second dielectric layer than that for a material of the first dielectric layer.

6. The method of claim 1, further comprising removing the first dielectric layer prior to performing the bonding process.

7. The method of claim 1, wherein depositing the first dielectric layer comprises:
depositing a first portion of the first dielectric layer on a top surface of the interconnect structure; and
depositing a second portion of the first dielectric layer on a sidewall of the interconnect structure.

8. The method of claim 1, wherein depositing the first dielectric layer comprises depositing a portion of the first dielectric layer on sidewalls of the interconnect structure, the device layer, and the substrate.

9. The method of claim 1, wherein depositing the first dielectric layer comprises depositing a nitride layer at a deposition temperature less than about 400° C.

10. The method of claim 1, further comprising depositing a third dielectric layer on a portion of the substrate in the peripheral region prior to forming the device layer on the substrate.

11. A method, comprising:
depositing a first dielectric layer on a first portion of a substrate in a peripheral region of an integrated circuit (IC) chip;
forming a fin structure on a second portion of the substrate in a device region of the IC chip;
forming a trench in the fin structure;
depositing a second dielectric layer in the trench and on top surfaces of the fin structure and the first dielectric layer;
performing a polishing process on the second dielectric layer to substantially coplanarize a top surface of the second dielectric layer with the top surface of the first dielectric layer;
forming a source/drain (S/D) region on the fin structure; and
depositing an interlayer dielectric (ILD) layer on the S/D region and on the first dielectric layer.

12. The method of claim 11, wherein depositing the first dielectric layer comprises:
depositing a first portion of the first dielectric layer on a top surface of the substrate; and
depositing a second portion of the first dielectric layer on a sidewall of the substrate.

13. The method of claim 11, wherein depositing the first dielectric layer comprises depositing a nitride layer.

14. The method of claim 11, wherein depositing the second dielectric layer comprises depositing an oxide layer.

15. The method of claim 11, further comprising depositing a third dielectric layer on a portion of the ILD layer in the peripheral region.

16. The method of claim 15, further comprising forming, on the S/D region, a contact structure with a top surface substantially planarized with a top surface of the third dielectric layer.

17. A semiconductor structure, comprising:
a first integrated circuit (IC) chip comprising a device region and a peripheral region, wherein the first IC chip comprises:
a substrate,
a device layer disposed on the substrate,
an interconnect structure disposed on the device layer,
a nitride layer disposed on a first portion of the interconnect structure in the peripheral region, and
an oxide layer disposed on a second portion of the interconnect structure in the device region, wherein a top surface of the oxide layer is substantially coplanar with a top surface of the nitride layer; and
a second IC chip disposed on the oxide layer.

18. The semiconductor structure of claim 17, wherein a first portion of the nitride layer is disposed on a top surface of the interconnect structure, and
wherein a second portion of the nitride layer is disposed on sidewalls of the interconnect structure, the device layer, and the substrate.

19. The semiconductor structure of claim 17, wherein the nitride layer extends a distance of about 5 mm to about 10 mm from an edge of the substrate towards a center of the substrate.

20. The semiconductor substrate of claim 17, further comprising an other nitride layer disposed directly on a portion of the substrate in the peripheral region and on a sidewall of the substrate.
